(19) United States
(12) Patent Application Publication
(10) Pub. No.: US 2014/0368249 A1
(43) Pub. Date: Dec. 18, 2014

(54) DELAY CONTROL CIRCUIT

(71) Applicant: SK hynix Inc., Icheon-si Gyeonggi-do (KR)

(72) Inventor: Kwang Su LEE, Cheongju-si Chungcheongbuk-do (KR)

(73) Assignee: SK hynix Inc., Icheon-si Gyeonggi-do (KR)

(21) Appl. No.: 14/026,698

(22) Filed: Sep. 13, 2013

(30) Foreign Application Priority Data
Jun. 17, 2013 (KR) 10-2013-0068832

(51) Int. Cl. H03K 3/011

(52) U.S. Cl. CPC H03K 3/011
USPC 327/262; 327/261

(57) ABSTRACT

The present invention relates to a delay control circuit and technology in which the amount of delay can be regularly maintained although Process, Voltage, and Temperature (PVT) conditions are changed. The delay control circuit of the present invention includes a ZQ calibration unit configured to generate an impedance code into which a change of PVT conditions has been incorporated, a voltage trimming unit configured to control a level of a trimming voltage at a calibration node, and a delay compensation unit configured to compensate for the amount of delay by controlling an effective capacitance value of a capacitor.

### CROSS-REFERENCE TO RELATED APPLICATION

The present application claims priority under 35 U.S.C. §119 (a) to Korean application number 10-2013-0068832, filed on Jun. 17, 2013, in the Korean Intellectual Property Office, which is incorporated herein by reference in its entirety.

### BACKGROUND

1. Technical Field

The present invention relates to a delay control circuit, and more particularly, to a technology for constantly maintaining a delay amount even when PVT (process, voltage and temperature) conditions vary.

2. Related Art

Various semiconductor devices realized in the form of integrated circuit chips such as a central processing unit (CPU), a memory and a gate array are incorporated into various electrical products, such as a personal computer, a server or a workstation. In most cases, a semiconductor device includes a reception circuit for receiving various signals transmitted from an outside, through an input pad, and an output circuit for providing internal signals to an outside through an output pad.

As an operating speed of an electrical product is increased, the swing width of a signal interfaced between semiconductor devices is gradually reduced. The reason to this is to minimize a delay time that is required for transfer of the signal. However, an influence by external noise increases as the swing width of a signal is reduced, and the reflection of a signal attributable to impedance mismatching (also referred to as ‘mismatching’) at an interface terminal becomes serious.

Impedance mismatching occurs due to external noise, a variation in a power supply voltage, a variation in an operating temperature, a variation in a manufacturing process, etc. When impedance mismatching occurs, high speed transmission of data becomes difficult, and output data outputted from the data output terminal of a semiconductor device may be distorted.

Accordingly, if a reception side semiconductor device receives the distorted output signal through the input terminal thereof, problems such as a setup/hold fail or an erroneous determination of an input level may be frequently caused.

In particular, several methods have been attempted in order to minimize a change in a delay amount in response to a variation in PVT conditions. However, in a conventional delay control circuit, a change in a delay amount has a specific slope in response to a variation in the PVT conditions. That is, a specific delay amount change occurs in correspondence to a variation in PVT conditions, and the specific amount of delay has a specific distribution. This method can improve a margin to some extent because a change in the amount of delay is small in terms of a clock tCK, but control of the amount of delay according to a variation in PVT conditions is limited in a circuit that requires high precision.

### SUMMARY

A delay control circuit is described herein. In particular, the amount of delay is regularly maintained although PVT conditions are changed by controlling a delay time of a delay compensation unit using a ZQ calibration code.

In an embodiment of the present invention, a delay control circuit includes a ZQ calibration unit configured to generate an impedance code into which a change of PVT conditions has been incorporated, a voltage trimming unit configured to control a level of a trimming voltage at a calibration node in response to the impedance code, and a delay compensation unit configured to compensate for the amount of delay by controlling an effective capacitance value of a capacitor in response to the trimming voltage.

In an embodiment of the present invention, a delay control circuit includes a ZQ calibration unit configured to generate an impedance code to maintain an impedance value at a target value; a voltage trimming unit configured to output a trimming voltage to a delay compensation unit; and the delay compensation unit configured to configured to output an output clock by compensating a delay of an input clock.

### BRIEF DESCRIPTION OF THE DRAWINGS

FIG. 1 shows the construction of a delay control circuit in accordance with an embodiment of the present invention;

FIG. 2 shows a detailed construction of a ZQ calibration unit in accordance with an embodiment of FIG. 1;

FIG. 3 is a detailed circuit diagram of a reference voltage generator of FIG. 2;

FIG. 4 is a detailed circuit diagram of a voltage trimming unit in accordance with an embodiment of FIG. 1; and

FIG. 5 is a detailed circuit diagram of a delay compensation unit in accordance with an embodiment of FIG. 1.

### DETAILED DESCRIPTION

Hereinafter, a delay control circuit according to the present invention is described in detail below with reference to the accompanying drawings through various embodiments.

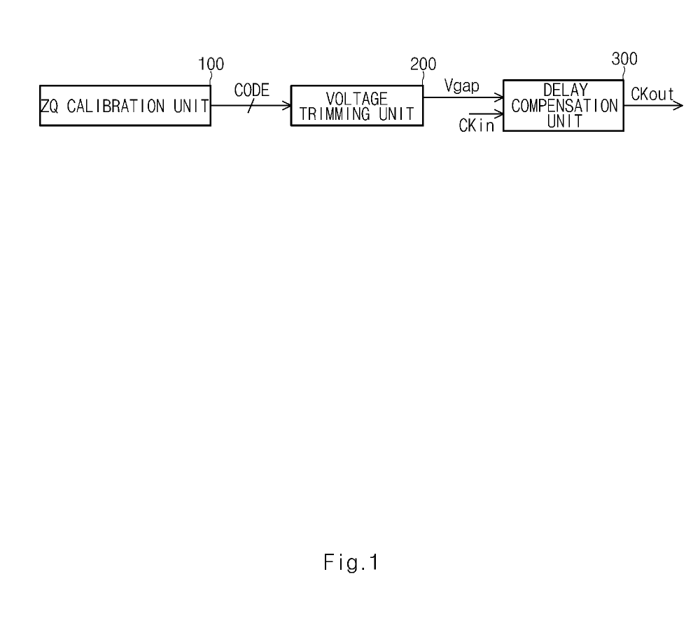

FIG. 1 shows the construction of the delay control circuit in accordance with an embodiment of the present invention.

The delay control circuit in accordance with an embodiment of the present invention may include a ZQ calibration unit 100, a voltage trimming unit 200, and a delay compensation unit 300.

The ZQ calibration unit 100 may generate an impedance code CODE of N bits for always maintaining an impedance value at a target value although PVT conditions are changed.

A termination impedance value at a calibration node ZQ is controlled using the impedance code CODE generated from the ZQ calibration unit 100.

Furthermore, the voltage trimming unit 200 may control a level of a trimming voltage Vgap in response to the impedance code CODE and output the controlled trimming voltage Vgap to the delay compensation unit 300. The delay compensation unit 300 may output an output clock CKout by compensating delay of an input clock CKin in response to the trimming voltage Vgap.

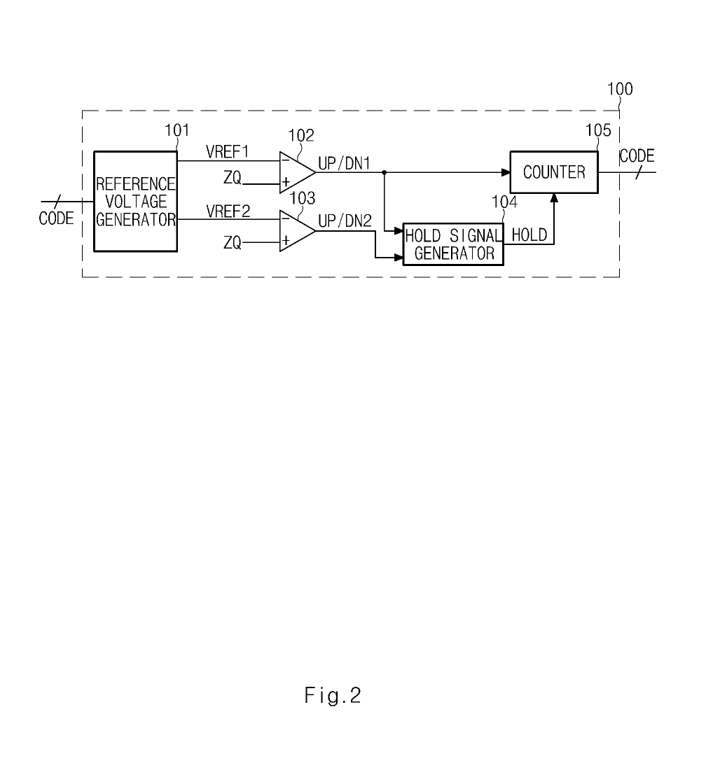

FIG. 2 shows a detailed construction of the ZQ calibration unit 100 in accordance with an embodiment of FIG. 1.

The ZQ calibration unit 100 may include a reference voltage generator 101, comparators 102 and 103, a hold signal generator 104, and a counter 105.

The reference voltage generator 101 may generate two reference voltages VREF1 and VREF2 in response to the impedance code CODE. A difference between levels of the two reference voltages VREF1 and VREF2 used in the reference voltage generator 101 is controlled in response to the impedance code CODE. That is, the reference voltage generator 101 may change levels of the reference voltages VREF1 and VREF2 depending on to which range the impedance code CODE belongs.

The two reference voltages VREF1 and VREF2 may have a target voltage +α and a target voltage −α on the basis of a target voltage that the calibration node ZQ needs to finally have. If a target voltage is set to VDD/2, the reference voltage VREF1 may have a value of ‘VDD/2+α’ and the reference voltage VREF2 may have a value of ‘VDD/2−α’. Here, a value of ‘α’ determines a margin of a calibration operation.

The comparator 102 may compare voltage at the calibration node ZQ with the reference voltage VREF1 and generate a comparison signal UP/DN1 based on a result of the comparison. The comparator 103 may compare voltage at the calibration node ZQ with the reference voltage VREF2 and generate a comparison signal UP/DN2 based on a result of the comparison.

The hold signal generator 104 may deactivate a hold signal HOLD when the comparison signal UP/DN1 and the comparison signal UP/DN2 have different values. In contrast, the hold signal generator 104 may activate the hold signal HOLD only when the comparison signal UP/DN1 and the comparison signal UP/DN2 have the same value.

The counter 105 may count the impedance code CODE, that is, a binary code, in response to the comparison signal UP/DN1. The counter 105 may generate the impedance code CODE so that voltage at the calibration node ZQ has a level between the reference voltage VREF1 and the reference voltage VREF2.

In an embodiment of the present invention, the counter 105 has been illustrated as increasing or decreasing a value of the impedance code CODE in response to the comparison signal UP/DN1. In an embodiment, the counter 105 may be configured to operate in response to the comparison signal UP/DN2 instead of the comparison signal UP/DN1 in order to derive the same results.

Here, the impedance code CODE can be generated in such a way as to increase or decrease a value of the impedance code CODE depending on a logic value of the comparison signal UP/DN1. The counter 105 may operate when the hold signal HOLD is deactivated. When the hold signal HOLD is activated, the operation of the counter 105 may be held. Here, the meaning ‘holding the operation’ may mean that a value of the impedance code CODE is fixed without changing the value.

The impedance code CODE generated from the counter 105 may turn on or off the code input unit 220 of the voltage trimming unit 200, thus determining the entire impedance value of the voltage trimming unit 200.

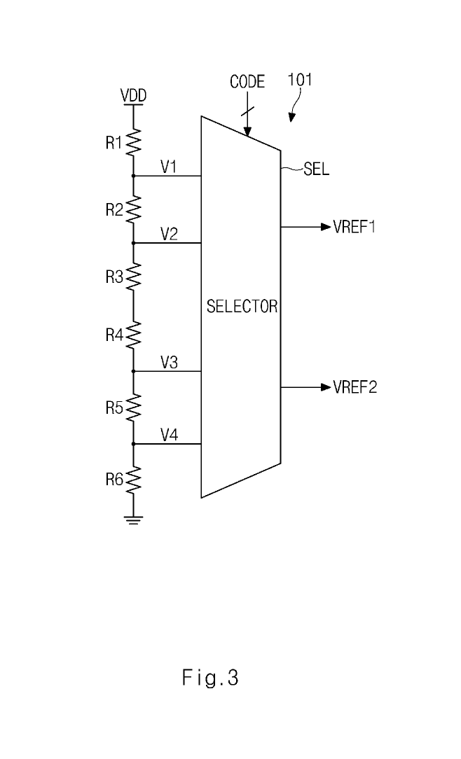

FIG. 3 is a detailed circuit diagram of the reference voltage generator 101 of FIG. 2.

The reference voltage generator 101 may include a plurality of resistors R1 to R6 and a selector SEL.

The plurality of resistors R1 to R6 may be coupled in series between a terminal for a source voltage VDD and a terminal for a ground voltage in order to generate a plurality of division voltages V1 to V4.

The selector SEL may select the reference voltage VREF1 and the reference voltage VREF2 from the plurality of division voltages V1 to V4 in response to a value of the impedance code CODE and outputs the reference voltage VREF1 and the reference voltage VREF2.

Furthermore, the selector SEL may select the division voltage V1 as the reference voltage VREF1 and the division voltage V4 as the reference voltage VREF2 in which the width of a change in the impedance value of the voltage trimming unit 200 due to a change of a value of the impedance code CODE is great. Furthermore, the selector SEL may select the division voltage V2 as the reference voltage VREF1 and the division voltage V3 as the reference voltage VREF2 in which the width of a change in the impedance value of the voltage trimming unit 200 due to a change of a value of the impedance code CODE is small.

For example, when the impedance code CODE is greater than (1,1,0,0,0), the division voltage V1 may be selected as the reference voltage VREF1 and the division voltage V4 may be selected as the reference voltage VREF2. In contrast, when the impedance code CODE is smaller than (1,1,0,0,0), the division voltage V2 may be selected as the reference voltage VREF1 and the division voltage V3 may be selected as the reference voltage VREF2.

Here, regarding the resistance values of the resistors R1 to R6, it is preferred that R1=R6, R2=R5, and R3=R4. If the resistance values of the resistors R1 to R6 are set as described above, the reference voltage VREF1 and the reference voltage VREF2 may have the same margin on the basis of VDD/2. That is, it may result in VREF1=‘VDD/2+α’ and VREF2=‘VDD/2−α’.

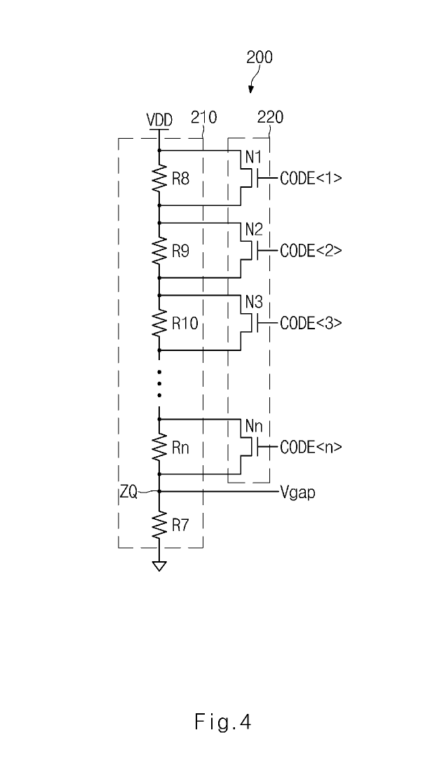

FIG. 4 is a detailed circuit diagram of the voltage trimming unit 200 in accordance with an embodiment of FIG. 1.

The voltage trimming unit 200 may include a voltage division unit 210 and the code input unit 220.

The voltage division unit 210 may include a plurality of resistors R7 to Rn coupled in series between the terminal for the source voltage VDD and the terminal for the ground voltage is supplied. The voltage division unit 210 may output the trimming voltage Vgap through the calibration node ZQ between the resistor R7 and the resistor Rn.

Furthermore, the resistor R7 may be connected to the calibration node ZQ of the voltage division unit 210. The resistor R7 is a resistor, that is, a reference for a calibration operation. Voltage at the calibration node ZQ may become lower as the entire impedance value (or resistance value) of the resistors R8 to Rn becomes greater, and voltage at the calibration node ZQ becomes higher as the entire impedance value (or resistance value) of the resistors R8 to Rn becomes smaller.

The code input unit 220 may include a plurality of switches coupled in parallel to the respective resistors R8 to Rn. The plurality of switches may include NMOS transistors N1 to Nn. The NMOS transistors N1 to Nn be coupled in parallel to respective nodes to which the plurality of resistors R1 to Rn is coupled. The NMOS transistors N1 to Nn may be supplied with respective impedance codes CODE1 to CODEn through their gate terminals.

The code input unit 220 may control the number of resistors R8 to Rn that are driven based on an impedance value determined by the impedance code CODE. The voltage division unit 210 may control a resistance division value by selectively turning on or off the NMOS transistors N1 to Nn in response to respective impedance values of the impedance codes CODE1 to CODEn. Accordingly, the voltage trimming unit 200 may output the trimming voltage Vgap having a level varied depending on the characteristics of the NMOS transistors.

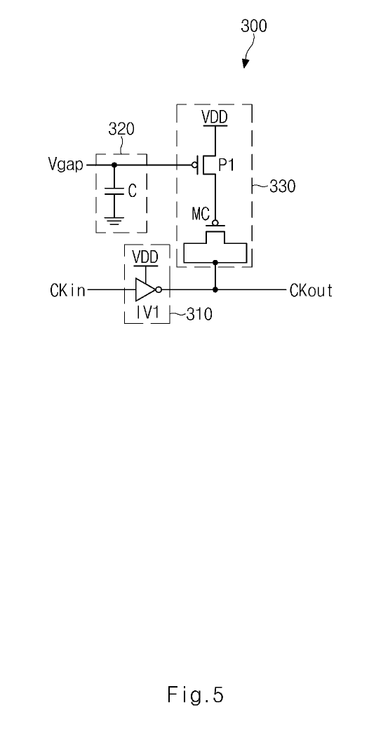

FIG. 5 is a detailed circuit diagram of the delay compensation unit 300 of FIG. 1.

The delay compensation unit 300 may include a clock driving unit 310, an input unit 320, and a compensation unit 330.

The clock driving unit 310 may include a compensation inverter IV1 and generate the output clock CKout by driving the input clock CKin. The compensation inverter IV1 may invert the input clock CKin in response to the source voltage VDD and output the output clock CKout.

The input unit 320 may filter and output the trimming voltage Vgap. The input unit 320 may include a capacitor C coupled between the input terminal of the trimming voltage Vgap and the terminal for the ground voltage.

The compensation unit 330 may compensate for RC delay of the input clock CKin by controlling the amount of charging of the output clock CKout in response to the trimming voltage Vgap.

The compensation unit 330 may include a switching element and a capacitor element. The switching element may include a PMOS transistor P1 coupled between the terminal for the source voltage VDD and the capacitor element and supplied with the trimming voltage Vgap through the gate terminal of the PMOS transistor P1. Furthermore, the capacitor element may include a MOS capacitor MC coupled between the drain terminal of the PMOS transistor P1 and the output terminal of the output clock CKout. The MOS capacitor MC can be a PMOS capacitor having a gate terminal coupled with the drain terminal of the PMOS transistor P1.

The operation of the delay control circuit constructed as above according to the present invention is described below.

The ZQ calibration unit 100 may generate the impedance code CODE of N bits for always maintaining an impedance value at a target value although PVT conditions are changed. A change of the impedance code CODE may lead to a change in the impedance value of the voltage division unit 210.

That is, the voltage division unit 210 may include a plurality of resistors R0 to Rn coupled in series between the terminal for the source voltage VDD and the terminal for the ground voltage. Voltage at the calibration node ZQ may be changed in response to a change in the impedance of the resistors R1 to Rn that varies in response to the impedance code CODE. Likewise, the changed voltage at the calibration node ZQ may change the impedance code CODE.

This operation may be repeatedly performed until the hold signal HOLD is activated. Here, the meaning that ‘the hold signal HOLD has been activated’ means that voltage at the calibration node ZQ becomes higher than the reference voltage VREF2, but becomes lower than the reference voltage VREF1.

When the ZQ calibration unit 100 operates, voltage at the calibration node ZQ may converge between the reference voltage VREF1 and the reference voltage VREF2. Furthermore, when the ZQ calibration unit 100 continues to operate, voltage at the calibration node ZQ may approach a level between the reference voltage VREF1 and the reference voltage VREF2. In accordance with this repetition operation, the entire impedance value of the resistors R1 to Rn becomes almost close to an impedance value of the resistor R0, that is, a reference resistor.

In other words, the ZQ calibration unit 100 may generate the impedance code CODE so that an impedance value of the voltage trimming unit 200 becomes similar to a value of the resistor R0 coupled with the calibration node ZQ. That is, the ZQ calibration unit 100 may generate the impedance code CODE so that voltage at the calibration node ZQ is higher than a level of the reference voltage VREF2, but is lower than a level of the reference voltage VREF1.

As a result, the impedance code CODE generated from the ZQ calibration unit 100 may control an impedance value of the voltage trimming unit 200. Accordingly, the clock driving unit 310 can be terminated in response to the trimming voltage Vgap having a precise impedance value although PVT conditions are changed.

In particular, a level of the trimming voltage Vgap of the voltage trimming unit 200 may be changed by the characteristics of the transistors, a change of a voltage, or a temperature. In an embodiment of the present invention, the characteristics of each device can be checked through the ZQ calibration unit 100, and the trimming voltage Vgap previously set based on the checked characteristics can be generated.

For example, in an embodiment of the present invention, in order to output the trimming voltage Vgap having a value predetermined in response to the specifications of a device, the reference voltages VREF1 and VREF2 of the reference voltage generator 430 can be controlled in response to a change of the transistors, a voltage, or a temperature. Accordingly, the voltage trimming unit 200 can generate the trimming voltage Vgap into which a change of PVT conditions has been incorporated.

Furthermore, voltage at the calibration node ZQ of the voltage division unit 210 may become lower as the entire impedance value (or resistance value) of the resistors R8 to Rn becomes greater, but become higher as the entire impedance value (or resistance value) of the resistors R8 to Rn becomes smaller.

For example, when the entire impedance value of the resistors R8 to Rn is greater than an impedance value of the resistor R7, the calibration node ZQ may have voltage lower than VDD/2. When the entire impedance value of the resistors R8 to Rn is smaller than an impedance value of the resistor R7, the calibration node ZQ may have voltage higher than VDD/2.

Furthermore, the code input unit 220 may control the number of resistors R8 to Rn that are driven based on an impedance value determined by the impedance code CODE. The voltage division to unit 210 may control a resistance division value of the voltage division unit 210 by selectively turning on or off the NMOS transistors N1 to Nn in response to respective values of the impedance codes CODE1 to CODEn. Accordingly, the trimming voltage Vgap having a controlled impedance value may be inputted to the delay compensation unit 300.

If the trimming voltage Vgap is controlled in response to a ZQ calibration value as described above, a value suitable for the characteristics of elements can be used. That is, since the trimming voltage Vgap is changed in response to a change in the characteristics of elements, the amount of delay of the delay compensation unit 300 can be regularly compensated for irrespective of a change of PVT conditions.

Thereafter, the trimming voltage Vgap may be inputted to the PMOS transistor P1 of the compensation unit 330. A gate-source voltage of the PMOS transistor P1 may be controlled in response to the trimming voltage Vgap, thereby compensating for a resistance value of the compensation unit 300.

That is, when the source voltage VDD is changed, the trimming voltage Vgap may be applied to the gate terminal of the PMOS transistor P1 in order to regularly control the amount of delay. Accordingly, turn-on resistance of the PMOS transistor P1 may be changed by changing a gate-source voltage of the PMOS transistor P1 in response to a change of the source voltage VDD.

Furthermore, the output voltage of the PMOS transistor P1 is inputted to the gate terminal of the MOS capacitor MC. Capacitance of the MOS capacitor MC may be controlled in response to voltage applied through the gate terminal of the MOS capacitor MC, thereby being capable of compensating for a capacitance value of the output clock CKout. That is, the amount of delay can be regularly maintained by changing an effective capacitance value of the MOS capacitor MC.

For example, if a level of the source voltage VDD is lowered, a gate-source voltage of the PMOS transistor P1 becomes low, but turn-on resistance of the PMOS transistor P1 becomes high. Accordingly, the amount of delay may be reduced because the capacitance loading of the MOS capacitor MC is reduced. In this case, the amount of delay can be compensated for because resistance of the output clock CKout is increased.

Furthermore, if a change is generated according to the state of a transistor or a temperature in the state in which the source voltage VDD has a constant level, the trimming voltage Vgap may be changed in response to the impedance code CODE. Accordingly, the delay compensation unit 300 may compensate for delay the state of the transistor or the temperature.

Accordingly, the compensation unit 330 may compensate for RC delay of the input clock CKin by charging the output clock CKout in response to the trimming voltage Vgap that varies, so that a circuit having a constant amount of delay although PVT conditions are changed can be implemented.

The present invention is advantageous in that the amount of delay can be regularly maintained although PVT conditions are changed.

While certain embodiments have been described above, it will be understood to those skilled in the art that the embodiments described are by way of example only. Accordingly, the delay control circuit described herein should not be limited based on the described embodiments. Rather, the circuit described herein should only be limited in light of the claims that follow when taken in conjunction with the above description and accompanying drawings.

1. A delay control circuit, comprising:
a ZQ calibration unit configured to generate an impedance code into which a change of Process, Voltage, and Temperature (PVT) conditions has been incorporated;
a voltage trimming unit configured to control a level of a trimming voltage at a calibration node in response to the impedance code; and
a delay compensation unit configured to compensate for an amount of delay by controlling an effective capacitance value of a capacitor in response to the trimming voltage,
wherein the ZQ calibration unit comprises a reference voltage generator configured to generate a first reference voltage and a second reference voltage in response to the impedance code, and
wherein the ZQ calibration unit controls the impedance code by previously change levels of the first reference voltage and the second reference voltage in response to specifications of a device.

2. The delay control circuit of claim 1, wherein the ZQ calibration unit comprises:
a first comparator configured to compare voltage at the calibration node with the first reference voltage and generate a first comparison signal based on a result of the comparison;
a second comparator configured to compare the voltage at the calibration node with the second reference voltage and generate a second comparison signal based on a result of the comparison;
a hold signal generator configured to activate a hold signal when the first comparison is equal to the second comparison and output the hold signal; and
a counter configured to count the first comparison signal and generate the impedance code based on a result of the counting.

3. The delay control circuit of claim 1, wherein the reference voltage generator comprises:
a plurality of first resistors configured to generate a plurality of division voltages; and
a selector configured to select one voltage of the plurality of division voltages as the first reference voltage and another voltage of the plurality of division voltages as the second reference voltage in response to the impedance code.

4. The delay control circuit of claim 1, wherein the voltage trimming unit comprises:
a code input unit selectively switched in response to the impedance code; and
a voltage division unit configured to control the level of the trimming voltage in response to a switching state of the code input unit.

5. The delay control circuit of claim 1, wherein the delay compensation unit comprises:
a clock driving unit configured to generate an output clock by driving an input clock; and
a compensation unit configured to compensate for an amount of delay of the output clock in response to the trimming voltage.

6. The delay control circuit of claim 5, wherein the clock driving unit comprises an inverter for generating the output clock by inversely driving the input clock.

7. The delay control circuit of claim 5, wherein the delay compensation unit further comprises an input unit for filtering the trimming voltage and outputting the filtered trimming voltage.

8. The delay control circuit of claim 7, wherein the input unit comprises a capacitor coupled between a terminal to which the trimming voltage is inputted and a terminal for a ground voltage.

9. The delay control circuit of claim 5, wherein the compensation unit compensates for RC delay of the input clock by controlling an amount of charging of the output clock in response to the trimming voltage.

10. The delay control circuit of claim 5, wherein the compensation unit comprises:
a switching element switched in response to the trimming voltage and configured to selectively output a source voltage; and
a capacitor configured to have an effective capacitance value controlled in response to the output of the switching element.

11. The delay control circuit of claim 10, wherein the switching element comprises a PMOS transistor coupled between the terminal for the source voltage and the capacitor and configured to have the trimming voltage supplied through a gate terminal of the PMOS transistor.

12. The delay control circuit of claim 11, wherein turn-on resistance of the PMOS transistor is controlled in response to a gate-source voltage of the PMOS transistor varying in response to the trimming voltage.

13. The delay control circuit of claim 10, wherein the capacitor comprises a MOS capacitor coupled between the switching element and a terminal from which the output clock is outputted.

14. The delay control circuit of claim 13, wherein the MOS capacitor comprises a PMOS capacitor.

15. A delay control circuit, comprising:
a ZQ calibration unit configured to generate an impedance code to maintain an impedance value at a target value;
a voltage trimming unit configured to output a trimming voltage to a delay compensation unit; and
the delay compensation unit configured to configured to output an output clock by compensating a delay of an input clock,
wherein the ZQ calibration unit comprises a reference voltage generator configured to generate a first reference voltage and a second reference voltage in which a difference between levels of the first reference voltage and the second reference voltage are controlled in response to the impedance code, and
wherein the ZQ calibration unit controls the impedance code by previously change levels of a reference voltage in response to specifications of a device.

16. (canceled)

17. The delay circuit of claim 15, further comprising:
a first comparator configured to generate a first comparison signal in response to the first reference voltage and a calibration node voltage; and
a second comparator configured to generate a second comparison signal in response to the second reference voltage and the calibration node voltage.

18. The delay circuit of claim 17, further comprising:
a hold signal generator configured to activate a hold signal in response to a comparison between the first comparison signal and the second comparison signal; and
a counter configured to generate the impedance code to allow the calibration node voltage to have a level between the first reference voltage and the second reference voltage.

19. The delay circuit of claim 15, wherein the delay compensation unit comprises:
a clock driving unit configured to generate the output clock using a compensation inverter; and
a compensation unit configured to compensate for a delay of the input clock by controlling an amount of charging for the output clock.

20. The delay circuit of claim 19, wherein the compensation unit comprises:
a switching element supplied with the trimming voltage and configured to output a source voltage; and
a capacitor configured between the switching element and the output clock to have an effective capacitance value controlled.
